(19) United States
(12) Patent Application Publication
(10) Pub. No.: US 2026/0276737 A1
(43) Pub. Date: Sep. 17, 2026

(54) Leakage Detection Device, Leakage Detection Method, and Related Computer System

(71) Applicant: PowerX Semiconductor Corporation, Hsinchu County (TW)

(72) Inventor: An-Ching Lin, Hsinchu County (TW)

(73) Assignee: PowerX Semiconductor Corporation, Hsinchu County (TW)

(21) Appl. No.: 19/215,362

(22) Filed: May 22, 2025

(30) Foreign Application Priority Data
Mar. 11, 2025 (TW) 114108842

(51) Int. Cl. G01R 31/52; G01R 31/58; G06F 1/26

(52) U.S. Cl. CPC G01R 31/52; G01R 31/58; G06F 1/26

(57) ABSTRACT

A leakage detection device for a computer system includes a detection current generation circuit, coupled to a power line of a motherboard of the computer system, configured to generate a detection current; a voltage detection circuit, coupled to the power line, configured to detect a voltage value of the power line; and a control unit, coupled to the detection current generation circuit and the voltage detection circuit. When the computer system enters a first operating mode, the control unit controls the detection current generation circuit to output the detection current to the power line and controls the voltage detection circuit to detect the voltage value of the power line. This process determines a voltage variation curve of the power line relative to the detection current. The control unit then determines whether a leakage event occurs on the motherboard based on a voltage slope of the voltage variation curve.

### BACKGROUND OF THE INVENTION

### 1. Field of the Invention

The present invention relates to a leakage detection device, a leakage detection method, and a related computer system, and more particularly, to a leakage detection device, a leakage detection method, and a related computer system that effectively enhance system reliability.

### 2. Description of the Prior Art

During the assembly or transportation of a computer motherboard, capacitor components on the edges or backside of the motherboard are often damaged due to improper human operation. These damaged capacitors may cause electric leakage. If the electric leakage is not detected before the system is started up, it may lead to system instability or the burnout of other electronic components, which increases maintenance costs and negatively impacts user experience.

The leakage detection technology commonly adopted in the industry involves installing a set of voltage-dividing resistors on the power line of the motherboard, and measuring the voltage difference across these resistors to determine whether leakage occurs on the motherboard. Specifically, when the capacitor components on the motherboard are functioning normally, an expected voltage difference appears across the voltage-dividing resistors. However, when a capacitor is damaged and causes leakage, the leakage path alters the equivalent impedance of the circuit. This alteration causes the voltage difference across the resistors to deviate from the expected value, which allows the detection of a leakage condition on the motherboard.

However, such a hardware-based voltage division approach of leakage detection has several drawbacks. For instance, the use of fixed voltage-dividing resistors prevents adjustment of detection parameters based on the characteristics of different motherboards, resulting in a lack of design flexibility. Additionally, this approach can only detect severe leakage conditions that significantly alter impedance, but fails to effectively identify early anomalies where capacitor characteristics change slightly due to physical impact. Moreover, for the voltage division technique, leakage detection is performed only after the computer system is started up, preventing early warning. Furthermore, this technology does not record fault information, which hinders subsequent maintenance analysis.

In view of these shortcomings, there is a clear need to improve the conventional leakage detection technology for circuit boards.

### SUMMARY OF THE INVENTION

Therefore, the present invention primarily provides a leakage detection device, a leakage detection method, and a related computer system to address the deficiencies of the prior art.

An embodiment of the present invention discloses a leakage detection device for a computer system, which comprises a detection current generation circuit, coupled to a power line of a motherboard in the computer system, configured to generate a detection current; a voltage detection circuit, coupled to the power line, configured to detect a voltage value of the power line; and a control unit, coupled to the detection current generation circuit and the voltage detection circuit, configured to control the detection current generation circuit to output the detection current to the power line and control the voltage detection circuit to detect the voltage value of the power line when the computer system enters a first operating mode, thereby determining a voltage variation curve of the power line relative to the detection current, and configured to determine whether a leakage event occurs on the motherboard based on a voltage slope of the voltage variation curve.

Another embodiment of the present invention discloses a leakage detection method for a computer system, which comprises generating a detection current and outputting the detection current to a power line of a motherboard in the computer system when the computer system enters a first operating mode; detecting a voltage value of the power line to determine a voltage variation curve of the power line relative to the detection current; and determining whether a leakage event occurs on the motherboard based on a voltage slope of the voltage variation curve.

Another embodiment of the present invention discloses a computer system, which comprises a power supply, configured to provide power; a motherboard, comprising a plurality of electronic components and a power line electrically connected to the power supply and the electronic components; a power control module, disposed on the motherboard, configured to receive a status indication signal and an error indication signal, control the power supply accordingly, and generate a detection enable signal when the status indication signal indicates that the computer system enters a first operating mode; and a leakage detection device, disposed on the motherboard and coupled to the power line and the power control module, comprising a detection current generation circuit, coupled to the power line, configured to generate a detection current; a voltage detection circuit, coupled to the power line, configured to detect a voltage value of the power line; and a control unit, coupled to the detection current generation circuit and the voltage detection circuit, configured to control the detection current generation circuit to output the detection current to the power line and control the voltage detection circuit to detect the voltage value of the power line based on the detection enable signal, thereby determining a voltage variation curve of the power line relative to the detection current, and configured to determine whether a leakage event occurs on the motherboard based on a voltage slope of the voltage variation curve, so as to output the error indication signal to the power control module.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a computer system according to an embodiment of the present invention.

FIG. 2 is a schematic diagram of a leakage detection device according to an embodiment of the present invention.

FIG. 3 to FIG. 7 are schematic diagrams of related signals under different operating conditions of the computer system shown in FIG. 1.

FIG. 8 is a flowchart of a leakage detection method according to an embodiment of the present invention.

### DETAILED DESCRIPTION

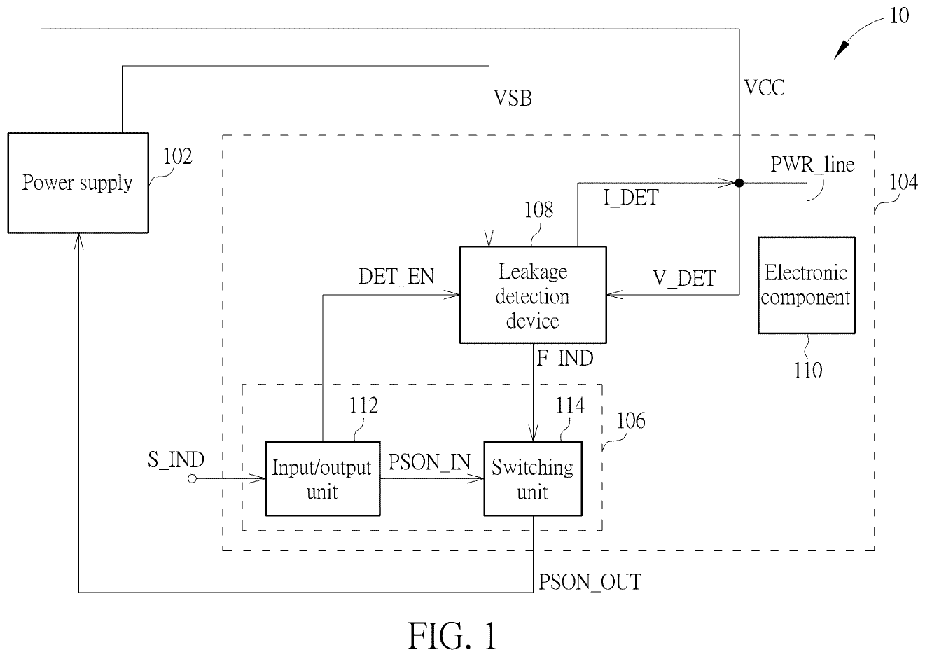

Please refer to FIG. 1, which is a schematic diagram of a computer system 10 according to an embodiment of the present invention. The computer system 10 can detect potential leakage risks before system startup, and generally comprises a power supply 102 and a motherboard 104. The motherboard 104 includes a power control module 106, a leakage detection device 108, and at least one electronic component 110. It should be noted that the implementation of a computer system is well-known to those skilled in the art. For brevity, FIG. 1 illustrates only the devices or modules relevant to the leakage detection functionality of the present invention. Other components, such as a central processing unit, hard disk, memory, display, and input/output devices, may be appropriately included without limitation. Specifically, the power supply 102 provides power, which, in this embodiment, includes a system power VCC and a standby power VSB. The system power VCC serves as the primary power source to drive the operation of the computer system 10 and is transmitted to the electronic component 110 via a power line PWR_line on the motherboard 104. The standby power VSB enables the computer system 10 to maintain necessary standby operations when the computer system 10 is shut down or in a sleep mode, and the standby power VSB is supplied to the leakage detection device 108. Although FIG. 1 depicts the power line PWR_line as a single line, this is not a limitation. The power line PWR_line may consist of a plurality of power rails, such as 12V, 5V, or 3.3V, to meet the power requirements of different components. Similarly, the electronic component 110 is represented as a single block in FIG. 1, but in practice, it may be a single electronic component, a group of a plurality of components connected in series or parallel, or a module composed of electronic components, and the components may include capacitors, inductors, resistors, or others, without limitation.

During the assembly or transportation of the computer system 10, the electronic component 110 may become damaged due to various factors, resulting in leakage. To address this, the leakage detection device 108 performs leakage detection when the computer system 10 is powered (e.g., receiving the standby power VSB) and in a shutdown state (hereinafter referred to as the first operating mode). In coordination with the power control module 106, the leakage detection device 108 can control the power supply 102 to stop outputting the system power VCC when a leakage risk is detected, thereby protecting the motherboard 104 from system instability or component burnout. In detail, the power control module 106 comprises an input/output unit 112 and a switching unit 114. The input/output unit 112 generates a first power control signal PSON_IN and a detection enable signal DET_EN based on a status indication signal S_IND, and outputs the first power control signal PSON_IN and the detection enable signal DET_EN to the switching unit 114 and the leakage detection device 108, respectively. The switching unit 114 generates a second power control signal PSON_OUT based on the first power control signal PSON_IN and an error indication signal F_IND that is outputted from the leakage detection device 108, to control the power supply 102. The status indication signal S_IND indicates the operating state of the computer system 10, which reflects either the power connection status or user commands. For example, in some cases, when the computer system 10 is powered but not yet started up by the user (i.e., the first operating mode) or when the user shuts down the system via an input device, the status indication signal S_IND indicates a shutdown state (i.e., an S5 state of the Advanced Configuration and Power Interface, ACPI); in other some cases, when the computer system 10 is powered (e.g., receiving the system power VCC) and the user presses a power button to start up the computer system 10, the status indication signal S_IND indicates a working state (i.e., an S0 state of ACPI). Similarly, the status indication signal S_IND may indicate other states, such as standby or sleep, which are well-known to those skilled in the art.

Based on the status indication signal S_IND, the input/output unit 112 can adjust the states of the first power control signal PSON_IN and the detection enable signal DET_EN. Specifically, when the status indication signal S_IND indicates a shutdown state, the input/output unit 112 sets the first power control signal PSON_IN to a disable state to instruct the termination of power output and further sets the detection enable signal DET_EN to an enable state to instruct the leakage detection device 108 to initiate leakage detection. Conversely, when the status indication signal S_IND indicates a working state, the input/output unit 112 sets the first power control signal PSON_IN to an enable state to instruct power output and further sets the detection enable signal DET_EN to a disable state to instruct the leakage detection device 108 to stop the leakage detection. In other words, the leakage detection device 108 performs the leakage detection in the first operating mode and generates the error indication signal F_IND or adjusts the state of the error indication signal F_IND accordingly.

The switching unit 114 generates and adjusts the state of the second power control signal PSON_OUT based on the first power control signal PSON_IN and the error indication signal F_IND to control the power supply 102. For example, when the second power control signal PSON_OUT is in the enable state, it activates the power supply 102 to output the system power VCC. When the second power control signal PSON_OUT is in the disable state, it stops the power supply 102 from outputting the system power VCC. In one embodiment, when the first power control signal PSON_IN is in the disable state, the second power control signal PSON_OUT outputted by the switching unit 114 is in the disable state. When the first power control signal PSON_IN is in the enable state and the error indication signal F_IND indicates that the leakage detection device 108 has not detected leakage, the second power control signal PSON_OUT outputted by the switching unit 114 is in the enable state. However, when the first power control signal PSON_IN is in the enable state but the error indication signal F_IND indicates that the leakage detection device 108 has detected leakage, the second power control signal PSON_OUT outputted by the switching unit 114 is in the disable state. In other words, when the error indication signal F_IND indicates a leakage event on the motherboard 104, the second power control signal PSON_OUT remains in the disable state even if the first power control signal PSON_IN is in the enable state, thereby preventing the power supply 102 from outputting the system power VCC and avoiding system instability or burnout.

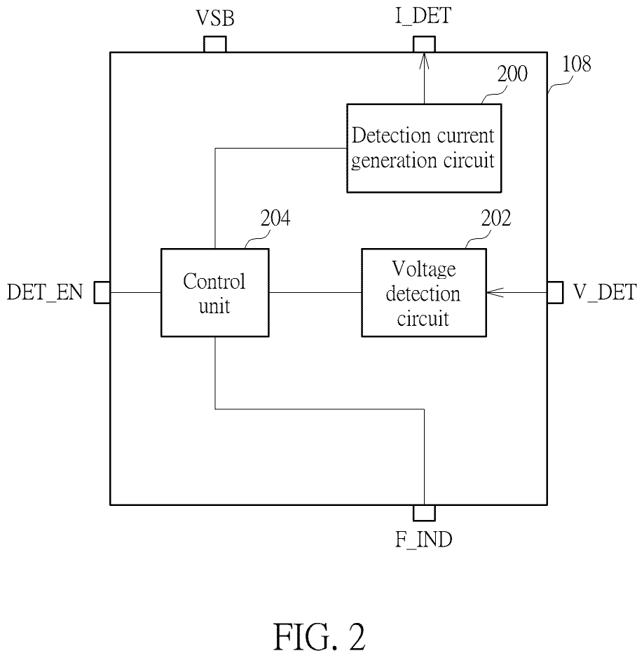

When the computer system 10 is powered (e.g., receiving the standby power VSB) and in the shutdown state (i.e., the first operating mode), the leakage detection device 108 performs leakage detection based on the detection enable signal DET_EN outputted from the power control module 106, and then generates the error indication signal F_IND or adjusts the state of the error indication signal F_IND accordingly. Please refer to FIG. 2, which is a schematic diagram of an embodiment of the leakage detection device 108. In this embodiment, the leakage detection device 108 comprises a detection current generation circuit 200, a voltage detection circuit 202, and a control unit 204. The detection current generation circuit 200 is coupled to the power line PWR_line and utilized to generate a detection current I_DET. The voltage detection circuit 202 is coupled to the power line PWR_line and utilized to detect a voltage value V_DET of the power line PWR_line. The control unit 204 receives the detection enable signal DET_EN and is coupled to both the detection current generation circuit 200 and the voltage detection circuit 202. When the computer system 10 enters the first operating mode, the control unit 204, based on the detection enable signal DET_EN, controls the detection current generation circuit 200 to output the detection current I_DET to the power line PWR_line and controls the voltage detection circuit 202 to detect the voltage value V_DET of the power line PWR_line, so as to determine a voltage variation curve of the power line PWR_line relative to the detection current I_DET. The control unit 204 then determines whether a leakage event occurs on the motherboard 104 based on a voltage slope of the voltage variation curve.

In detail, when the computer system 10 is powered and in the shutdown state, the input/output unit 112 outputs an enabled detection enable signal DET_EN to the leakage detection device 108, to prompt the leakage detection device 108 to initiate leakage detection. During the leakage detection, the control unit 204 controls the detection current generation circuit 200 to output the detection current I_DET to the power line PWR_line, which charges the electronic component 110. Simultaneously, the control unit 204 controls the voltage detection circuit 202 to detect the voltage value V_DET of the power line PWR_line, and the resulting voltage variation curve of the voltage value V_DET reflects the charging behavior of the electronic component 110 under the influence of the detection current I_DET. The control unit 204 then uses the voltage slope of the voltage variation curve to determine whether a leakage event occurs on the motherboard 104. For instance, if the electronic component 110 is damaged, it may cause an open circuit or a short circuit, resulting in an excessively high or low voltage slope of the voltage variation curve during the period when the electronic component 110 is charged by the detection current I_DET. Therefore, the control unit 204 compares the voltage slope of the voltage variation curve against a preset slope range. When the slope exceeds the preset slope range, the control unit 204 determines that the electronic component 110 is damaged, indicating a leakage event on the motherboard 104, such that the control unit 204 can generate or adjust the error indication signal F_IND to reflect occurrence of the leakage event. The switching unit 114, in response to the error indication signal F_IND indicating the leakage event, can output the second power control signal PSON_OUT in the disable state, to stop the power supply 102 from outputting the system power VCC, so as to prevent system instability or burnout.

In short, when the computer system 10 is powered and in the shutdown state (i.e., the first operating mode), the leakage detection device 108 outputs the detection current I_DET and measures the corresponding voltage value V_DET to determine the voltage variation curve during the charging of the electronic component 110. The control unit 204 compares the voltage slope of the voltage variation curve against a preset slope range to determine whether a leakage event occurs on the motherboard 104. Thus, the leakage detection device 108 can identify a leakage event before the computer system 10 is started up, which allows the power control module 106 to control the power supply 102 to stop outputting the system power VCC, thereby avoiding greater damage.

It should be noted that FIG. 2 represents one feasible embodiment of the leakage detection device 108, but variations are possible, and those skilled in the art may make modifications accordingly. For example, in one embodiment, the leakage detection device 108 may include an information interface. The control unit 204 can use the information interface to retrieve or update information related to the preset slope range or to output information about a leakage event, such as information about the specific electronic component 110 associated with the error indication signal F_IND. In another embodiment, the leakage detection device 108 may include a storage unit coupled to the control unit 204 for storing the preset slope range or recording leakage events on the motherboard 104. Since there are slight variations in characteristics of different motherboards, manufacturers or maintenance personnel can update the preset slope range via the information interface to match actual conditions. Additionally, because the motherboard 104 may include numerous electronic components, designers may deploy a plurality of leakage detection devices 108 on the motherboard 104 to monitor different electronic components individually or configure a single leakage detection device 108 to use time-division or multiplexing techniques to detect the states of the plurality of electronic components. In such cases, to assist maintenance personnel in identifying faulty components, the storage unit and information interface can record or output information about leakage events on the motherboard 104. However, the implementation is not limited to these examples; any method that provides leakage-related information can be incorporated into the leakage detection device 108 as appropriate.

When the computer system 10 enters the first operating mode, the control unit 204 controls the detection current generation circuit 200 to output the detection current I_DET for leakage detection. After the leakage detection is completed, the control unit 204 instructs the detection current generation circuit 200 to stop outputting the detection current I_DET. Furthermore, in one embodiment, when the computer system 10 exits the first operating mode and enters a second operating mode (e.g., the working state), the control unit 204 not only controls the detection current generation circuit 200 to stop outputting the detection current I_DET but also controls the voltage detection circuit 202 to continuously monitor the voltage value V_DET of the power line PWR_line, in order to determine whether the operating voltage of the system power VCC exceeds a predefined voltage range. When the operating voltage of the system power VCC exceeds the predefined voltage range, the control unit 204 outputs the error indication signal F_IND or adjusts the state of the error indication signal F_IND to shut down the power supply 102. In other words, when the computer system 10 operates in the working state, the leakage detection device 108 stops performing leakage detection but continuously determines whether the operating voltage of the system power VCC remains within the predefined voltage range. When the operating voltage of the system power VCC exceeds the predefined voltage range, the power supply 102 is turned off promptly to prevent system failure due to excessively high or low voltages. Note that, the storage unit and information interface can also be adapted for this voltage monitoring task. For instance, the control unit 204 can receive or update voltage range information via the interface, and store data about out-of-range events in the storage unit or output the data about out-of-range events to an external device via the interface. Such modifications are within the expertise of those skilled in the art.

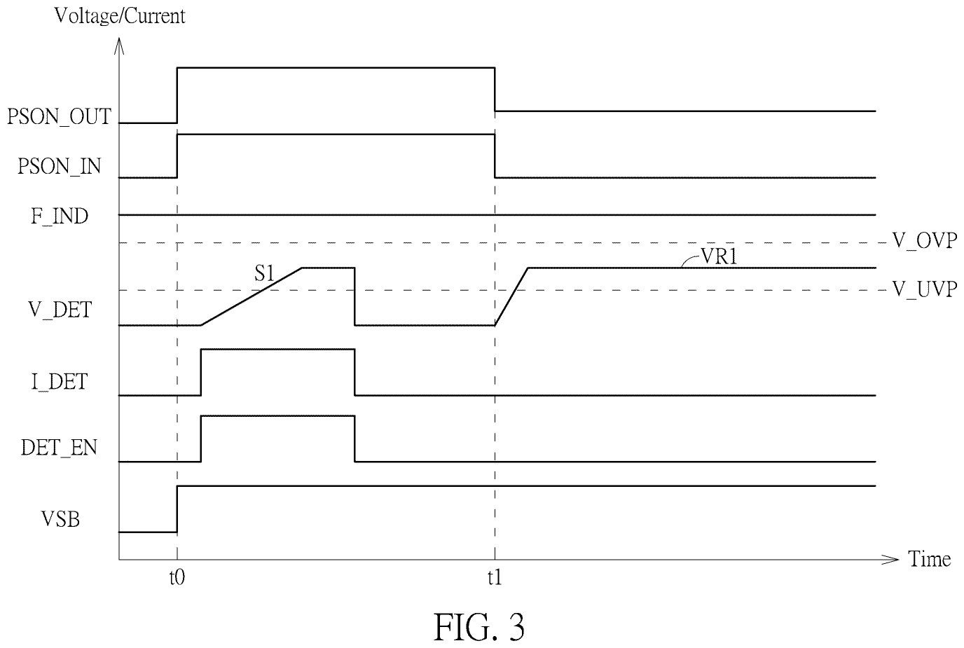

For further insight into the leakage detection and voltage monitoring operations of the computer system 10, please refer to FIG. 3 to FIG. 7, which illustrate schematic diagrams of relevant signals under various operating conditions of the computer system 10. Assume that the first power control signal PSON_IN and the second power control signal PSON_OUT are active-low signals, where a high level indicates the disable state and a low level indicates the enable state; a high-level error indication signal F_IND signifies a leakage event or an operating voltage of the system power VCC exceeding the voltage range; and the voltage range has an upper limit of V_OVP and a lower limit of V_UVP. First, as shown in FIG. 3, at time t0, the computer system 10 is powered, but the user has not yet started up the computer system 10. Thus, the computer system 10 is in the shutdown state (S5 state), and both the first power control signal PSON_IN and the second power control signal PSON_OUT remain at a high level (disable state). Meanwhile, the standby power VSB is supplied to the leakage detection device 108. Upon receiving an enabled detection enable signal DET_EN, the leakage detection device 108 initiates leakage detection. That is, the detection current generation circuit 200 outputs the detection current I_DET to charge the electronic component 110, and the voltage detection circuit 202 detects the voltage value V_DET, to obtain a voltage variation curve VR1 of the voltage value V_DET. The voltage variation curve VR1 reflects the charging behavior of the electronic component 110 under the detection current I_DET. In the case of FIG. 3, a voltage slope S1 of the voltage variation curve VR1 falls within the preset slope range, and the control unit 204 determines that no leakage event occurs and maintains the error indication signal F_IND at a low level. Next, at time t1, the user starts up the computer system 10, causing the first power control signal PSON_IN to switch to a low level (enable state). Since the error indication signal F_IND indicates no leakage event (low level), the switching unit 114 adjusts the second power control signal PSON_OUT to a low level, to prompt the power supply 102 to supply the system power VCC. Consequently, the computer system 10 operates normally in the working state (S0 state).

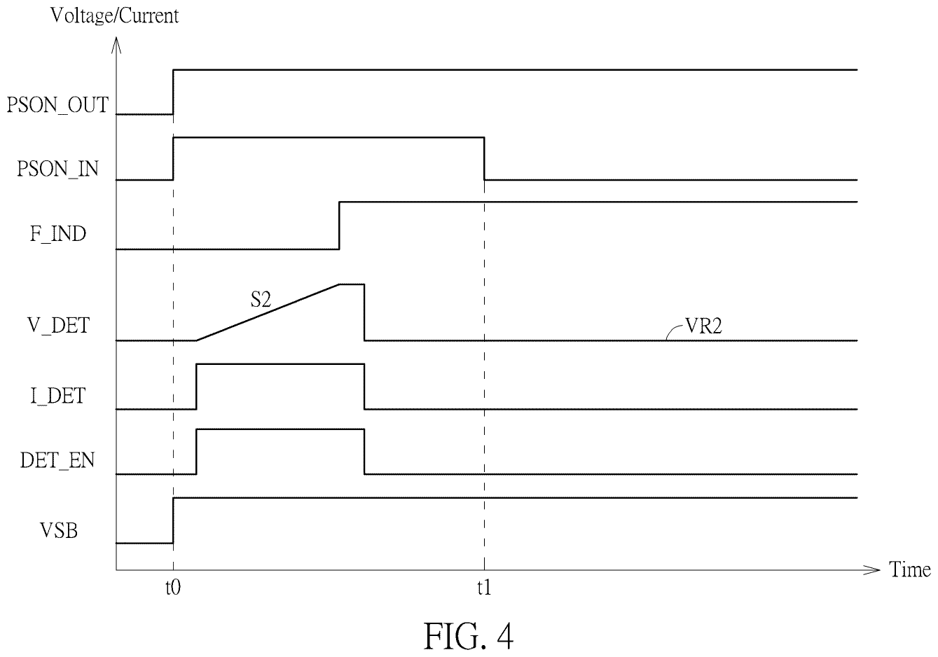

In the scenario depicted in FIG. 4, at time t0, the computer system 10 is powered but not yet started up by the user. Thus, the computer system 10 is in the shutdown state (S5 state), and the first power control signal PSON_IN and the second power control signal PSON_OUT stay at a high level (disable state). Meanwhile, the standby power VSB is supplied to the leakage detection device 108. Upon receiving an enabled detection enable signal DET_EN, the leakage detection device 108 initiates leakage detection. That is, the detection current generation circuit 200 outputs the detection current I_DET to charge the electronic component 110, and the voltage detection circuit 202 detects or measures the voltage value V_DET, to obtain a voltage variation curve VR2 of the voltage value V_DET. The voltage variation curve VR2 reflects the charging behavior of the electronic component 110 under the detection current I_DET. In the case of FIG. 4, a voltage slope S2 of the voltage variation curve VR2 falls outside the preset slope range, and the control unit 204 determines occurrence of a leakage event. Accordingly, the control unit 204 sets the error indication signal F_IND to a high level. Next, at time t1, the user starts up the computer system 10, which switches the first power control signal PSON_IN to a low level (enable state). However, since the error indication signal F_IND indicates occurrence of a leakage event (high level), the switching unit 114 keeps the second power control signal PSON_OUT at a high level, preventing the power supply 102 from supplying the system power VCC. Thus, the computer system 10 remains in the shutdown state (S5 state). Meanwhile, the control unit 204 records relevant information for fault diagnosis during maintenance.

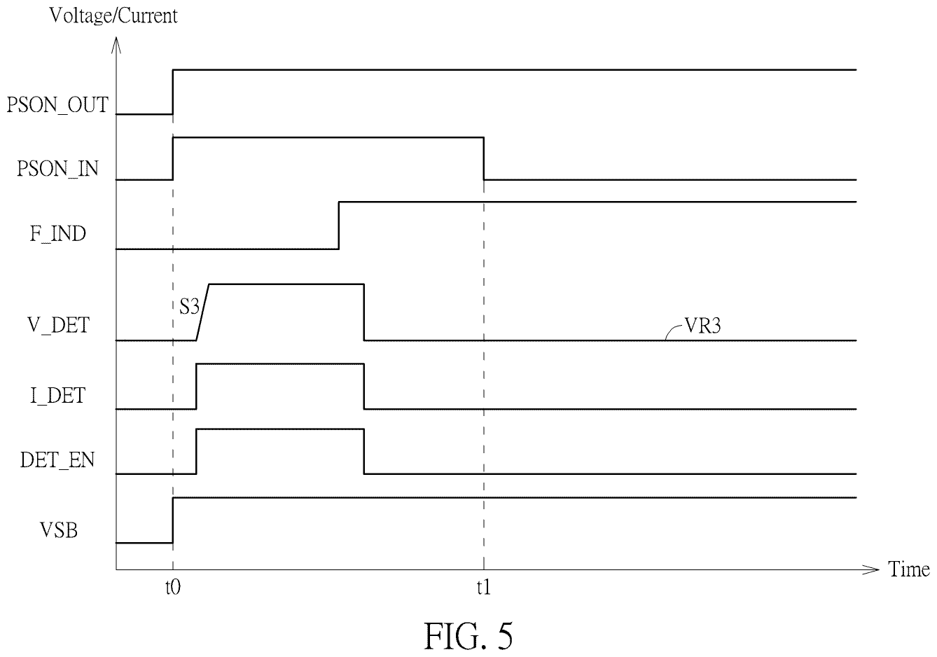

The scenario in FIG. 5 is similar to that in FIG. 4, except that the voltage slope S2 in FIG. 4 is below the preset slope range, whereas a voltage slope S3 of a voltage variation curve VR3 in FIG. 5 exceeds the preset slope range. In both cases, the control unit 204 identifies a leakage event, sets the error indication signal F_IND to a high level, prevents the power supply 102 from supplying the system power VCC, and keeps the computer system 10 in the shutdown state (S5 state). The control unit 204 may also recode relevant fault information for maintenance purposes.

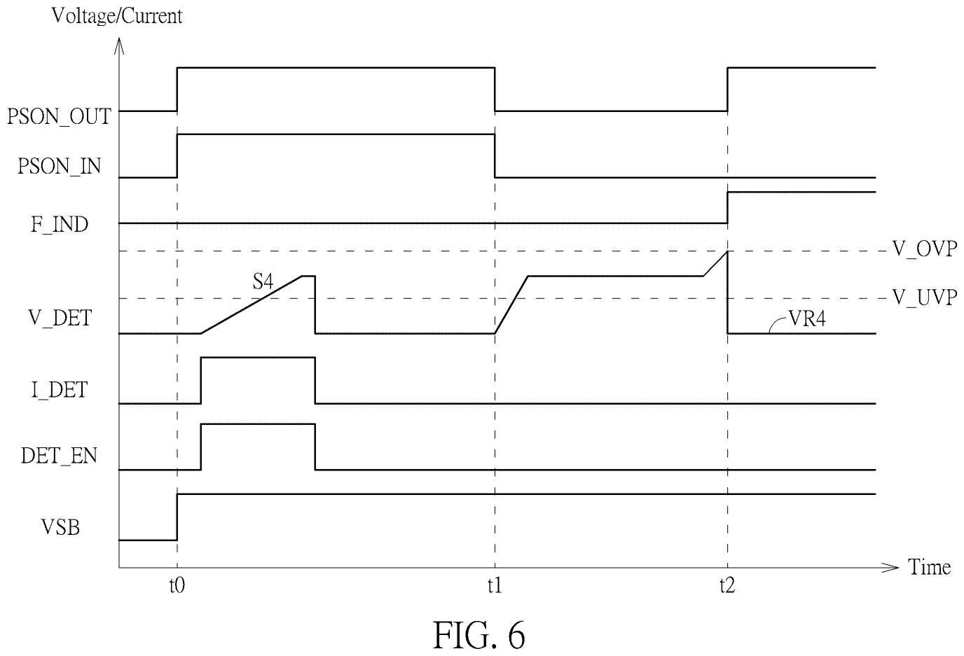

In FIG. 6, a voltage variation curve VR4 between times t0 and t1 mirrors the voltage variation curve VR1 in FIG. 3. In response to a voltage slope S4 of the voltage variation curve VR4 falling within the preset slope range, the control unit 204 detects no leakage event and keeps the error indication signal F_IND at a low level. At time t1, the user starts up the computer system 10, which switches the first power control signal PSON_IN to a low level (enable state). Since no leakage event is indicated by the error indication signal F_IND (low level), the switching unit 114 sets the second power control signal PSON_OUT to a low level, to enable the power supply 102 to supply the system power VCC, and the computer system 10 enters the working state (S0 state). In the working state, the leakage detection device 108 controls the detection current generation circuit 200 to stop outputting the detection current I_DET and further controls the voltage detection circuit 202 to detect the voltage value V_DET of the power line PWR_line continuously, so as to determine whether the operating voltage of the system power VCC exceeds the voltage range. At time t2, the voltage variation curve VR4 shows that the operating voltage of the system power VCC exceeds the upper limit V_OVP. Thus, the control unit 204 sets the error indication signal F_IND to a high level, to prompt the switching unit 114 to switch the second power control signal PSON_OUT to a high level, which stops the power supply 102 from supplying the system power VCC and causes the computer system 10 to switch from the working state to the shutdown state. Meanwhile, the control unit 204 may recode fault information for maintenance purposes.

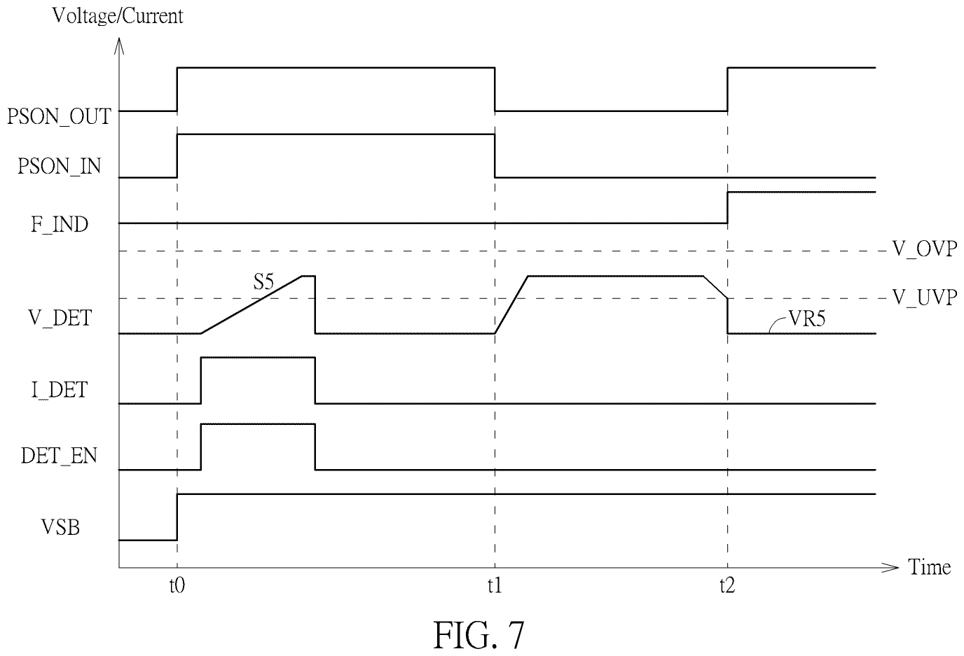

FIG. 7 is similar to FIG. 6, where a voltage slope S5 of a voltage variation curve VR5 between times t0 and t1 falls within the preset slope range. The control unit 204 detects no leakage event and keeps the error indication signal F_IND at a low level. At time t2, the scenario in FIG. 7 differs from that in FIG. 6. The voltage variation curve VR5, which is obtained by the voltage detection circuit 202 detecting the voltage value V_DET, shows that the operating voltage of the system power VCC drops below the lower limit V_UVP. The control unit 204 sets the error indication signal F_IND to a high level, and the switching unit 114 switches the second power control signal PSON_OUT to a high level, to stop the power supply 102 from supplying the system power VCC and switch the computer system 10 from the working state to the shutdown state. Meanwhile, the control unit 204 may recode fault information for maintenance purposes.

As can be known from FIG. 3 to FIG. 7, the leakage detection device 108 enables the computer system 10 to detect potential leakage risks before startup and record fault data, which can aid maintenance personnel in rapid problem diagnosis.

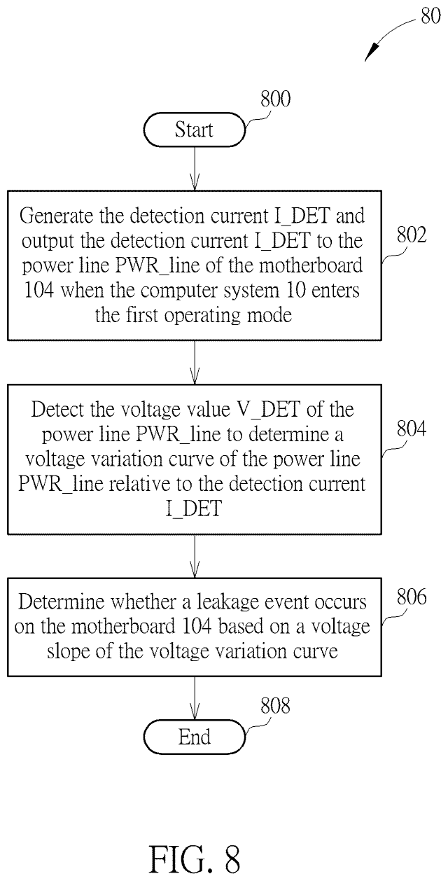

The operation of the leakage detection device 108 can be summarized as a leakage detection method 80, illustrated in FIG. 8. The leakage detection method 80 includes the following steps:
Step 800: Start.
Step 802: Generate the detection current I_DET and output the detection current I_DET to the power line PWR_line of the motherboard 104 when the computer system 10 enters the first operating mode.
Step 804: Detect the voltage value V_DET of the power line PWR_line to determine a voltage variation curve of the power line PWR_line relative to the detection current I_DET.
Step 806: Determine whether a leakage event occurs on the motherboard 104 based on a voltage slope of the voltage variation curve.
Step 808: End.

Detailed operations and variations of the leakage detection method 80 are described earlier and are not repeated here.

It is worth noting that the above embodiments illustrate the concept of the present invention, and those skilled in the art may make modifications without limitation. For example, if the power line PWR_line comprises a plurality of power rails, the leakage detection device 108 can test each rail individually. For example, when the computer system 10 enters the first operating mode (e.g., powered but not yet started up), the control unit 204 can control the detection current generation circuit 200 to output an appropriate detection current I_DET to each rail and further control the voltage detection circuit 202 to detect or measure the voltage value V_DET for each rail. This can be achieved through time-division output or multiplexing with corresponding detection methods, and is not limited to these approaches. Additionally, the computer system 10 refers broadly to any electronic system with computing capabilities, such as a desktop computer, laptop, server, communication device, or industrial control system, without restriction.

To detect motherboard leakage, the conventional techniques use fixed voltage-dividing resistors, which lack flexibility, cannot provide early warnings, fail to record fault data, and complicate maintenance analysis. In contrast, the leakage detection architecture of the present invention identifies risks before start-up and monitors the system power during operation, offering comprehensive power oversight to protect the motherboard and prevent severe damage. The present invention also records and outputs fault information, to enable accurate identification of faulty components. Thus, the leakage detection architecture of the present invention enhances system reliability and facilitates fault analysis.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A leakage detection device for a computer system, comprising:
a detection current generation circuit, coupled to a power line of a motherboard in the computer system, configured to generate a detection current;
a voltage detection circuit, coupled to the power line, configured to detect a voltage value of the power line; and
a control unit, coupled to the detection current generation circuit and the voltage detection circuit, configured to control the detection current generation circuit to output the detection current to the power line and control the voltage detection circuit to detect the voltage value of the power line when the computer system enters a first operating mode, thereby determining a voltage variation curve of the power line relative to the detection current, and configured to determine whether a leakage event occurs on the motherboard based on a voltage slope of the voltage variation curve.

2. The leakage detection device of claim 1, wherein the control unit compares the voltage slope of the voltage variation curve against a preset slope range to determine whether the leakage event occurs on the motherboard.

3. The leakage detection device of claim 2, further comprising an information interface, wherein the control unit retrieves information related to the preset slope range through the information interface.

4. The leakage detection device of claim 2, wherein when the voltage slope exceeds the preset slope range, the control unit is further configured to determine that the leakage event occurs on the motherboard and output an error indication signal, which is used to shut down a power supply of the computer system.

5. The leakage detection device of claim 1, wherein when the computer system enters a second operating mode, the control unit is further configured to control the detection current generation circuit to stop outputting the detection current to the power line and control the voltage detection circuit to detect the voltage value of the power line to detect an operating voltage of the power line.

6. The leakage detection device of claim 5, wherein when the operating voltage of the power line exceeds a voltage range, the control unit is further configured to output an error indication signal, which is used to shut down a power supply of the computer system.

7. The leakage detection device of claim 5, wherein the second operating mode is a working state.

8. The leakage detection device of claim 1, further comprising a storage unit, coupled to the control unit, for recording the leakage event on the motherboard.

9. The leakage detection device of claim 1, wherein the power line comprises a plurality of power rails, wherein when the computer system enters the first operating mode, the control unit controls the detection current generation circuit to respectively output detection currents appropriate for the plurality of power rails to the power line and further control the voltage detection circuit to detect a voltage value for each of the plurality of power rails.

10. The leakage detection device of claim 1, wherein the first operating mode is a shutdown state of the computer system which is powered.

11. A leakage detection method for a computer system, comprising:
generating a detection current and outputting the detection current to a power line of a motherboard in the computer system when the computer system enters a first operating mode;
detecting a voltage value of the power line to determine a voltage variation curve of the power line relative to the detection current; and
determining whether a leakage event occurs on the motherboard based on a voltage slope of the voltage variation curve.

12. The leakage detection method of claim 11, wherein the step of determining whether the leakage event occurs on the motherboard comprises comparing the voltage slope of the voltage variation curve against a preset slope range.

13. The leakage detection method of claim 12, further comprising when the voltage slope exceeds the preset slope range, determining that a leakage event occurs on the motherboard and outputting an error indication signal, which is used to shut down a power supply of the computer system.

14. The leakage detection method of claim 11, further comprising when the computer system enters a second operating mode, controlling the detection current generation circuit to stop outputting the detection current to the power line and controlling the voltage detection circuit to detect the voltage value of the power line to detect an operating voltage of the power line.

15. The leakage detection method of claim 14, further comprising when the operating voltage of the power line exceeds a voltage range, outputting an error indication signal, which is used to shut down a power supply of the computer system.

16. The leakage detection method of claim 15, wherein the second operating mode is a working state.

17. The leakage detection method of claim 11, further comprising recording the leakage event on the motherboard.

18. The leakage detection method of claim 11, wherein the power line comprises a plurality of power rails, wherein when the computer system enters the first operating mode, the step of generating the detection current and outputting the detection current to the power line of the motherboard in the computer system comprises respectively outputting detection currents appropriate for the plurality of power rails to the power line, and the step of detecting the voltage value of the power line comprises detecting a voltage value for each of the plurality of power rails.

19. The leakage detection method of claim 11, wherein the first operating mode is a shutdown state of the computer system which is powered.

20. A computer system, comprising:
a power supply, configured to provide power;
a motherboard, comprising a plurality of electronic components and a power line electrically connected to the power supply and the electronic components;
a power control module, disposed on the motherboard, configured to receive a status indication signal and an error indication signal, control the power supply accordingly, and generate a detection enable signal when the status indication signal indicates that the computer system enters a first operating mode; and
a leakage detection device, disposed on the motherboard and coupled to the power line and the power control module, comprising:
a detection current generation circuit, coupled to the power line, configured to generate a detection current;
a voltage detection circuit, coupled to the power line, configured to detect a voltage value of the power line; and
a control unit, coupled to the detection current generation circuit and the voltage detection circuit, configured to control the detection current generation circuit to output the detection current to the power line and control the voltage detection circuit to detect the voltage value of the power line based on the detection enable signal, thereby determining a voltage variation curve of the power line relative to the detection current, and configured to determine whether a leakage event occurs on the motherboard based on a voltage slope of the voltage variation curve, so as to output the error indication signal to the power control module.
